(19) United States
(12) Patent Application Publication
(10) Pub. No.: US 2026/0181923 A1
(43) Pub. Date: Jun. 25, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Tatsuya OHGURO, Yokohama Kanagawa (JP); Susumu OBATA, Yokohama Kanagawa (JP); Kazuhito HIGUCHI, Yokohama Kanagawa (JP)

(21) Appl. No.: 19/313,685

(22) Filed: Aug. 28, 2025

(30) Foreign Application Priority Data
Dec. 19, 2024 (JP) 2024-223763

(51) Int. Cl. H10D 1/68

(52) U.S. Cl. CPC H10D 1/716

(57) ABSTRACT

According to one embodiment, a semiconductor device includes a semiconductor member, a first insulating layer, a first conductive member, a second insulating layer, a first via resistance portion, a first conductive layer, and a second conductive layer. The first insulating layer is provided on the semiconductor member. The first conductive layer is electrically connected to the first via resistance portion. The second conductive layer is electrically connected to the semiconductor member. The semiconductor member is provided on the second conductive layer. The first conductive layer includes a first portion, a second portion, and a third portion. The second portion is between the first portion and the third portion. The third portion is on the first via resistance portion. The first portion, the second portion, and the third portion are electrically connected to the first via resistance portion.

### CROSS-REFERENCE TO RELATED APPLICATIONS

This application is based upon and claims the benefit of priority from Japanese Patent Application No. 2024-223763, filed on Dec. 19, 2024; the entire contents of which are incorporated herein by reference.

### FIELD

Embodiments described herein relate generally to a semiconductor device.

### BACKGROUND

For example, it is desirable to improve the characteristics of a semiconductor device such as a capacitor using silicon.

### BRIEF DESCRIPTION OF THE DRAWINGS

FIG. 1A is a schematic plan view illustrating a semiconductor device according to an embodiment;

FIG. 1B is a schematic cross-sectional view illustrating the semiconductor device according to the embodiment;

FIG. 2 is an equivalent circuit diagram illustrating the semiconductor device according to the embodiment;

FIG. 3A is a schematic plan view illustrating a semiconductor device according to the embodiment;

FIG. 3B is a schematic cross-sectional view illustrating the semiconductor device according to the embodiment;

FIG. 4A is a schematic plan view illustrating a semiconductor device according to the embodiment;

FIG. 4B is a schematic cross-sectional view illustrating the semiconductor device according to the embodiment;

FIG. 5A is a schematic plan view illustrating a semiconductor device according to the embodiment;

FIG. 5B is a schematic cross-sectional view illustrating the semiconductor device according to the embodiment;

FIG. 6A is a schematic plan view illustrating a semiconductor device according to the embodiment;

FIG. 6B is a schematic cross-sectional view illustrating the semiconductor device according to the embodiment;

FIG. 7A is a schematic plan view illustrating a semiconductor device according to the embodiment;

FIG. 7B is a schematic cross-sectional view illustrating the semiconductor device according to the embodiment;

FIG. 8 is a schematic cross-sectional view illustrating a semiconductor device according to the embodiment;

FIG. 9 is an equivalent circuit diagram illustrating the semiconductor device according to the embodiment;

FIG. 10A is a schematic plan view illustrating a semiconductor device according to the embodiment;

FIG. 10B is a schematic cross-sectional view illustrating the semiconductor device according to the embodiment;

FIG. 11A is a schematic plan view illustrating a semiconductor device according to the embodiment; and

FIG. 11B is a schematic cross-sectional view illustrating the semiconductor device according to the embodiment.

### DETAILED DESCRIPTION

According to one embodiment, a semiconductor device includes a semiconductor member, a first insulating layer, a first conductive member, a second insulating layer, a first via resistance portion, a first conductive layer, and a second conductive layer. The first insulating layer is provided on the semiconductor member. The first conductive member is provided on the first insulating layer. The second insulating layer is provided on the first conductive member. The first via resistance portion is provided on a part of the first conductive member. The first via resistance portion penetrates a part of the second insulating layer in a first direction. The first via resistance portion is electrically connected to the first conductive member. The first conductive layer is provided on the first via resistance portion. The first conductive layer is electrically connected to the first via resistance portion. The second conductive layer is electrically connected to the semiconductor member. The semiconductor member is provided on the second conductive layer. The first conductive layer includes a first portion, a second portion, and a third portion. The second portion is between the first portion and the third portion. The third portion is on the first via resistance portion. The first portion, the second portion, and the third portion are electrically connected to the first via resistance portion. The second portion includes a meander wiring.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

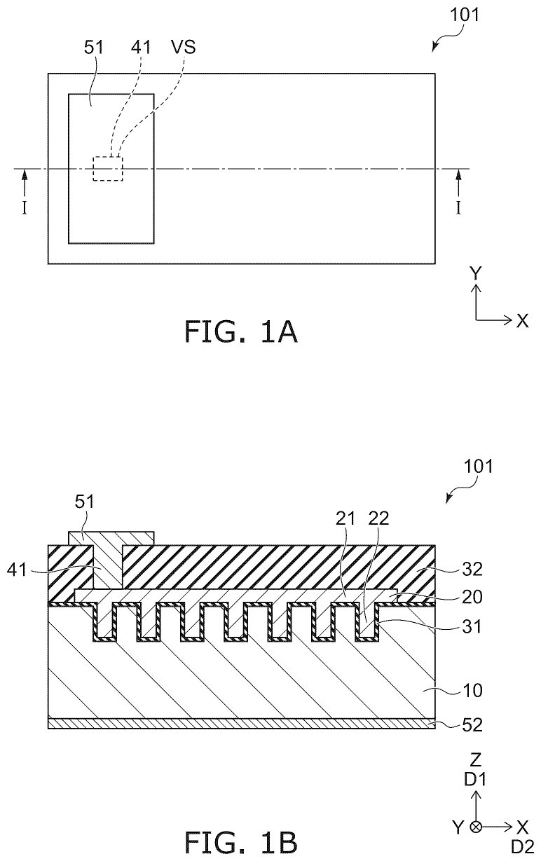

FIG. 1A is a schematic plan view illustrating a semiconductor device according to an embodiment.

FIG. 1B is a schematic cross-sectional view illustrating the semiconductor device according to the embodiment. FIG. 1B is a cross-sectional view taken along line I-I of FIG. 1A.

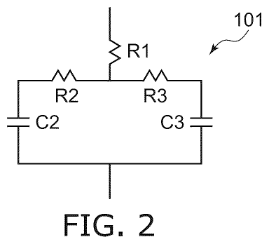

As shown in FIGS. 1A and 2, a semiconductor device 101 according to a first embodiment includes a semiconductor member 10, a first insulating layer 31, a first conductive member 20, a second insulating layer 32, and a first via resistance portion 41.

One direction perpendicular to an X-axis direction is defined as a Y-axis direction. One direction perpendicular to the X-axis direction and the Y-axis direction is defined as a Z-axis direction. The Z-axis direction is, for example, a first direction D1. The X-axis direction is, for example, a second direction D2.

The first insulating layer 31 is provided on the semiconductor member 10. The first conductive member 20 is provided on the first insulating layer 31. The second insulating layer 32 is provided on the first conductive member 20. The first via resistance portion 41 is provided on a part of the first conductive member 20. The first via resistance portion 41 penetrates a part of the second insulating layer 32 in the first direction D1. The first via resistance portion 41 is electrically connected to the first conductive member 20.

The semiconductor member 10 functions as, for example, an electrode. The first conductive member 20 functions as, for example, another electrode. A voltage may be applied between the semiconductor member 10 and the first conductive member 20. The semiconductor member 10, the first conductive member 20, and the first insulating layer 31 function as, for example, a capacitor. The first via resistance portion 41 is a resistor. The semiconductor device 101 is, for example, a capacitor including a resistor. The semiconductor device 101 is, for example, an RC snubber circuit.

FIG. 2 is an equivalent circuit diagram illustrating the semiconductor device according to the embodiment.

A capacitor C2 shown in FIG. 2 corresponds to the semiconductor member 10, the first conductive member 20, and the first insulating layer 31. A capacitor C3 corresponds to the semiconductor member 10, the first conductive member 20, and the first insulating layer 31. A resistor R2 corresponds to the first conductive member 20. A resistor R3 corresponds to the first conductive member 20. A resistor R1 corresponds to the first via resistance portion 41.

In the semiconductor device 101, a via resistor (the first via resistance portion 41) is used. Accordingly, since the parasitic inductance is lower than in a case of using an Al wiring as a resistor, the overshoot of the drain voltage when the voltage is off can be reduced, and a loss when the voltage is off can be reduced. Which of the effects is produced is determined by a combination of the resistance value and the capacitance value. Further, since the number of processes is smaller than in a case of using a poly resistor, manufacturing costs can be reduced.

The semiconductor member 10 may include silicon. The semiconductor device 101 is, for example, a silicon capacitor. The semiconductor member 10 includes any of phosphorus, arsenic, or boron as an impurity. The concentration of the impurity is 1E19 cm⁻³ or more. The concentration may be a concentration in the entire semiconductor member 10 or in the surface of a first conductive region 21 formed on the semiconductor member 10.

The first conductive member 20 is, for example, polysilicon or polysilicon germanium, and may include phosphorus, arsenic, or boron.

The number of via resistance portions, such as the first via resistance portions 41, may be one or more.

The total area VS of the first via resistance portion 41 may be 1000 μm² or more and 3000000 μm² or less. The total area VS is, for example, an area along the X-Y plane.

The first conductive member 20 may include the first conductive region 21 and a plurality of protruding portions 22. The plurality of protruding portions 22 are provided between the semiconductor member 10 and the first conductive region 21. The first conductive member 20 may be a resistor.

As shown in FIGS. 1A and 1B, the semiconductor device 101 may further include a first conductive layer 51 and a second conductive layer 52.

The first conductive layer 51 is provided on the first via resistance portion 41. The first conductive layer 51 is electrically connected to the first via resistance portion 41.

The second conductive layer 52 is electrically connected to the semiconductor member 10. The semiconductor member 10 is provided on the second conductive layer 52.

The first conductive layer 51 and the second conductive layer 52 function as terminals.

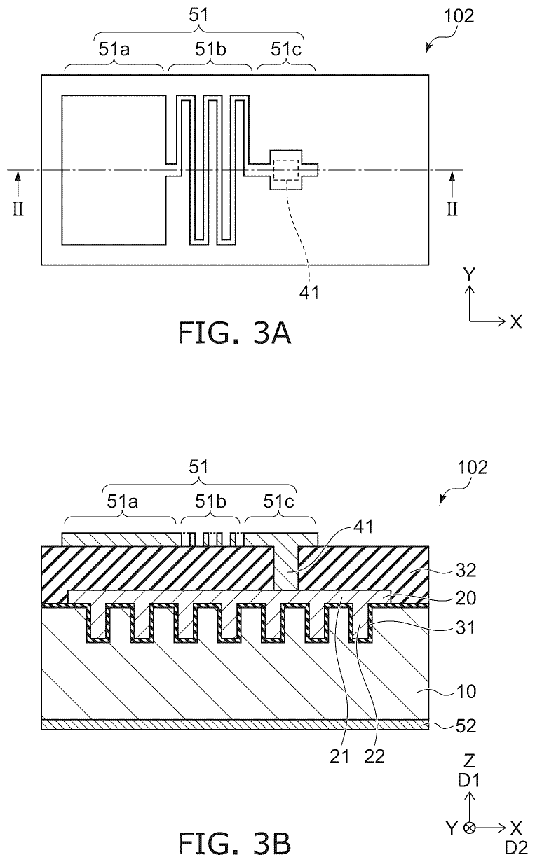

FIG. 3A is a schematic plan view illustrating a semiconductor device according to the embodiment.

FIG. 3B is a schematic cross-sectional view illustrating the semiconductor device according to the embodiment. FIG. 3B is a cross-sectional view taken along line II-II of FIG. 3A.

As shown in FIGS. 3A and 3B, the first conductive layer 51 may further include a first portion 51a, a second portion 51b, and a third portion 51c. The configuration of a semiconductor device 102 may be otherwise similar to the configuration of the semiconductor device 101.

The second portion 51b is between the first portion 51a and the third portion 51c. The third portion 51c is on the first via resistance portion 41.

The first portion 51a, the second portion 51b, and the third portion 51c are electrically connected to the first via resistance portion 41.

The second portion 51b functions as a resistor.

The first portion 51a is electrically connected to the first conductive member 20 via the second portion 51b, the third portion 51c, and the first via resistance portion 41.

The second portion 51b may include a meander wiring.

The first insulating layer 31 may include Si, O, N, Hf, Ti, Mg, or Al. The second insulating layer 32 may include Si, O, or N. The first via resistance portion 41 may include any of Al, Si, Cu, Ti, N, W, Co, or Ni. The first portion 51a may include Al. The second portion 51b may include any of Al, Si, Cu, Ti, N, W, Co, or Ni. The third portion 51c may include any of Al, Si, Cu, Ti, N, W, Co, or Ni. The second conductive layer 52 may include any of Al, Ti, Ni, Au, Ag, or Pd.

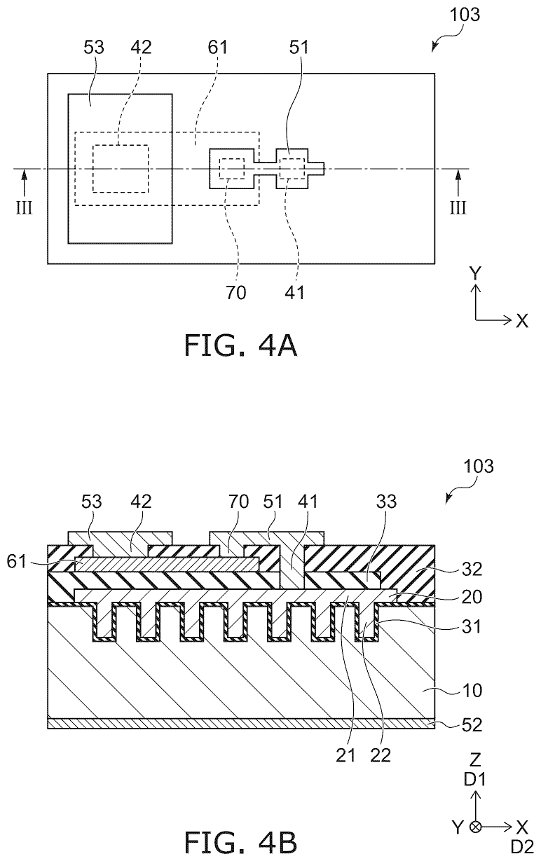

FIG. 4A is a schematic plan view illustrating a semiconductor device according to the embodiment.

FIG. 4B is a schematic cross-sectional view illustrating the semiconductor device according to the embodiment. FIG. 4B is a cross-sectional view taken along line III-III of FIG. 4A.

As shown in FIGS. 4A and 4B, a semiconductor device 103 may include a third insulating layer 33, a first wiring resistance portion 61, a second via resistance portion 42, a third conductive layer 53, and a connection portion 70. The first via resistance portion 41 penetrates the second insulating layer 32 and the third insulating layer 33. The configuration of the semiconductor device 103 may be otherwise similar to the configuration of the semiconductor device 101.

The third insulating layer 33 is provided on a part of the first conductive member 20. The third insulating layer 33 may or may not be provided around the first via resistance portion 41 between the first conductive member 20 and the second insulating layer 32.

The first wiring resistance portion 61 is provided on the third insulating layer 33.

The second via resistance portion 42 is provided on a part of the first wiring resistance portion 61. The second via resistance portion 42 penetrates a part of the second insulating layer 32 in the first direction D1. The second via resistance portion 42 is electrically connected to the first conductive layer 51 via the first wiring resistance portion 61.

The third conductive layer 53 is provided on the second via resistance portion 42.

The resistance of the first wiring resistance portion 61 may be larger than the resistance of the first via resistance portion 41. The resistance of the first wiring resistance portion 61 may be larger than the resistance of the second via resistance portion 42.

The third insulating layer 33 may include Si, O, or N. The second via resistance portion 42 may include Al. The third conductive layer 53 may include any of Al, Si, Cu, Ti, N, W, Co, or Ni. The first wiring resistance portion 61 may include any of polysilicon or polysilicon germanium. The connection portion 70 may include any of Al, Si, Cu, Ti, N, W, Co, or Ni.

In the semiconductor device 103 shown in FIGS. 4A and 4B, the second conductive layer 52 and the third conductive layer 53 function as terminals. The third conductive layer 53 is electrically connected to the first conductive member 20 via the second via resistance portion 42, the first wiring resistance portion 61, the connection portion 70, the first conductive layer 51, and the first via resistance portion 41.

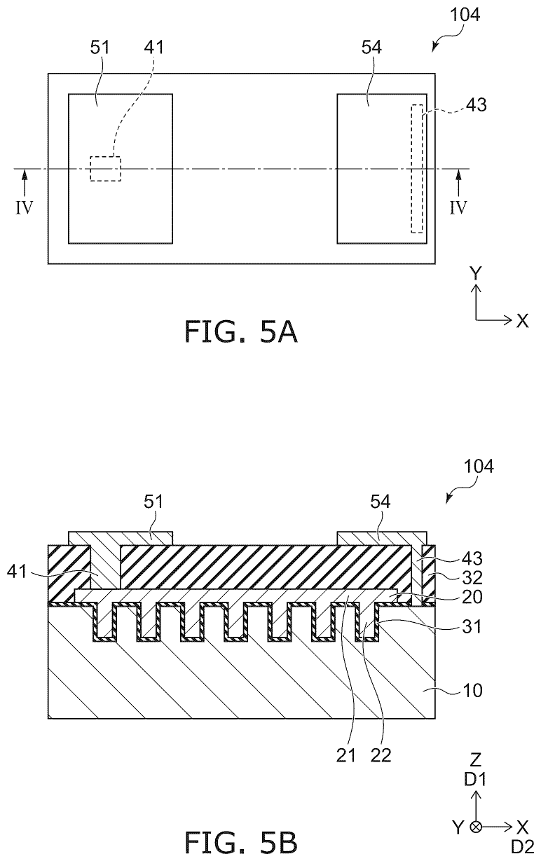

FIG. 5A is a schematic plan view illustrating a semiconductor device according to the embodiment.

FIG. 5B is a schematic cross-sectional view illustrating the semiconductor device according to the embodiment. FIG. 5B is a cross-sectional view taken along line IV-IV of FIG. 5A.

As shown in FIGS. 5A and 5B, a semiconductor device 104 may further include a third via resistance portion 43 and a fourth conductive layer 54. In the semiconductor device 104 shown in FIGS. 5A and 5B, the first conductive layer 51 and the fourth conductive layer 54 function as terminals. The configuration of the semiconductor device 104 may be otherwise similar to the configuration of the semiconductor device 101.

The third via resistance portion 43 is provided on the semiconductor member 10. The third via resistance portion 43 penetrates a part of the first insulating layer 31 and a part of the second insulating layer 32 in the first direction D1. The third via resistance portion 43 is electrically connected to the semiconductor member 10.

The fourth conductive layer 54 is provided on the third via resistance portion 43. The fourth conductive layer 54 is electrically connected to the semiconductor member 10 via the third via resistance portion 43.

The third via resistance portion 43 may include any of Al, Si, Cu, Ti, N, W, Co, or Ni. The fourth conductive layer 54 may include any of Al, Si, Cu, Ti, N, W, Co, or Ni.

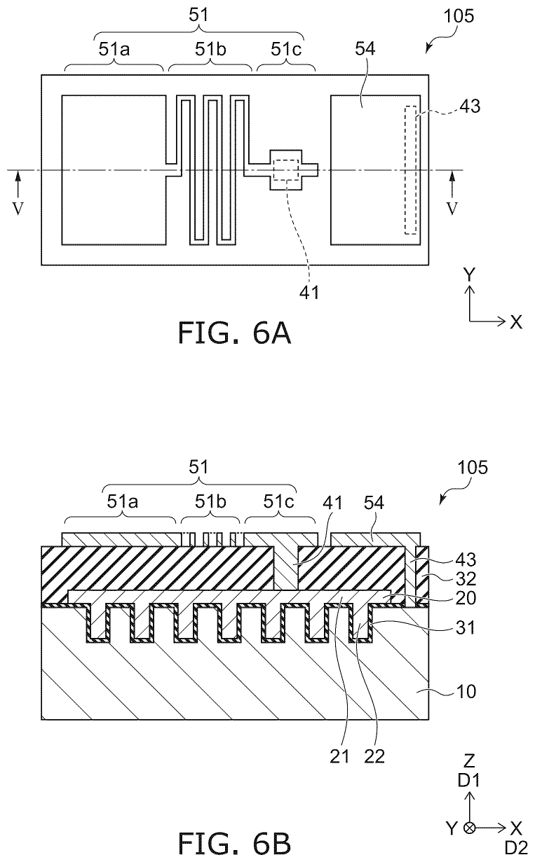

FIG. 6A is a schematic plan view illustrating a semiconductor device according to the embodiment.

FIG. 6B is a schematic cross-sectional view illustrating the semiconductor device according to the embodiment. FIG. 6B is a cross-sectional view taken along line V-V of FIG. 6A.

As shown in FIGS. 6A and 6B, the first conductive layer 51 may further include the first portion 51a, the second portion 51b, and the third portion 51c. The configuration of a semiconductor device 105 may be otherwise similar to the configuration of the semiconductor device 104.

The second portion 51b is between the first portion 51a and the third portion 51c. The third portion 51c is on the first via resistance portion 41. The second portion 51b may include Al.

The first portion 51a, the second portion 51b, and the third portion 51c are electrically connected to the first via resistance portion 41. The second portion 51b functions as a resistor. The first portion 51a is electrically connected to the first conductive member 20 via the second portion 51b, the third portion 51c, and the first via resistance portion 41.

The first portion 51b may include a meander wiring.

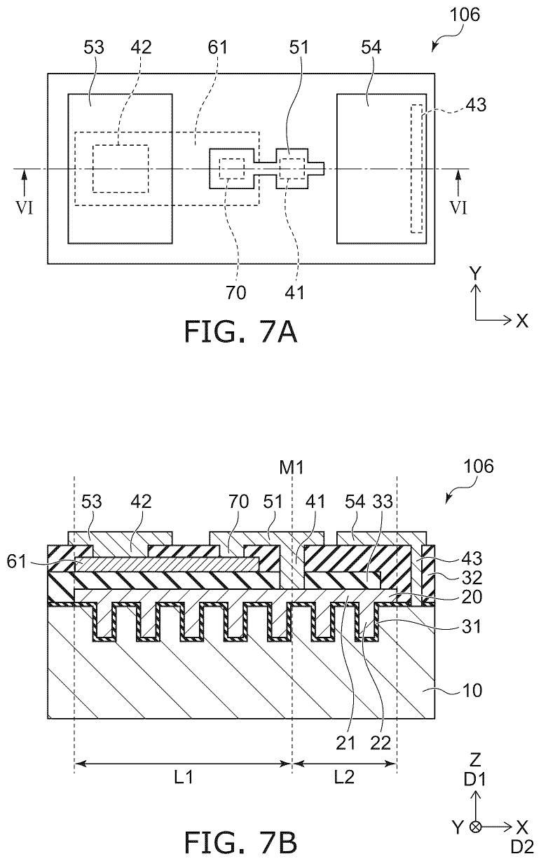

FIG. 7A is a schematic plan view illustrating a semiconductor device according to the embodiment.

FIG. 7B is a schematic cross-sectional view illustrating the semiconductor device according to the embodiment. FIG. 7B is a cross-sectional view taken along line VI-VI of FIG. 7A.

As shown in FIGS. 7A and 7B, a semiconductor device 106 may further include the third insulating layer 33, the first wiring resistance portion 61, the second via resistance portion 42, the third conductive layer 53, and the connection portion 70. In the semiconductor device 106 shown in FIGS. 7A and 7B, the third conductive layer 53 and the fourth conductive layer 54 function as terminals. The third conductive layer 53 is electrically connected to the first conductive member 20 via the second via resistance portion 42, the first wiring resistance portion 61, the connection portion 70, the first conductive layer 51, and the first via resistance portion 41. The configuration of the semiconductor device 106 may be otherwise similar to the configuration of the semiconductor device 104.

The third insulating layer 33 is provided on a part of the first conductive member 20.

The first wiring resistance portion 61 is provided on a part of the third insulating layer 33.

The second via resistance portion 42 is provided on the first wiring resistance portion 61. The second via resistance portion 42 penetrates a part of the second insulating layer 32 in the first direction D1. The second via resistance portion 42 is electrically connected to the first wiring resistance portion 61.

The third conductive layer 53 is provided on the second via resistance portion 42.

The resistance of the first wiring resistance portion 61 may be larger than the resistance of the first via resistance portion 41. The resistance of the first wiring resistance portion 61 may be larger than the resistance of the second via resistance portion 42.

The cutoff frequency determined by the reciprocal of the product of the resistance and the capacitance may be two times or more the operating frequency.

The cutoff frequency is derived from a delay time based on the electric resistance R and the capacitance C obtained by the following first expression (1).

$$R 1 = ρ s \times L 1 / W , C 1 = Cs \times L 1 \times W … ( 1 ) fT 1 = 1 / ( R 1 \times C 1 ) \qquad ( 1 )$$

$$R 2 = ρ s \times L 2 / W , C 2 = Cs \times L 2 \times W … ( 2 ) fT 2 = 1 / ( R 2 \times C 2 ) \qquad ( 2 )$$

L1 and L2 are selected by adjusting the position of the first via resistance portion 41 so that both of them become two times or more the operating frequency.

ρs is the sheet resistance of the first conductive member 20. Cs is the capacitance per unit area. L1 is the distance from the center M1 of the first via resistance portion 41 to one end portion of the first conductive member 20 in the second direction D2 (see FIG. 7B). L2 is the distance from the center of the first via resistance portion 41 to the other end portion of the first conductive member 20 in the second direction D2 (see FIG. 7B). W is the width of the first conductive member 20 in the Y-direction. L1×W and L2×W are the area of the first conductive member 20.

The first conductive layer 51 may include at least one selected from the group consisting of Zr, Hf, Ti, Pd, V, Co, Mo, Cr, W, Ni, Rh, Pt, Ir, N, and Al. Accordingly, a desired resistance of the first conductive layer 51 is obtained.

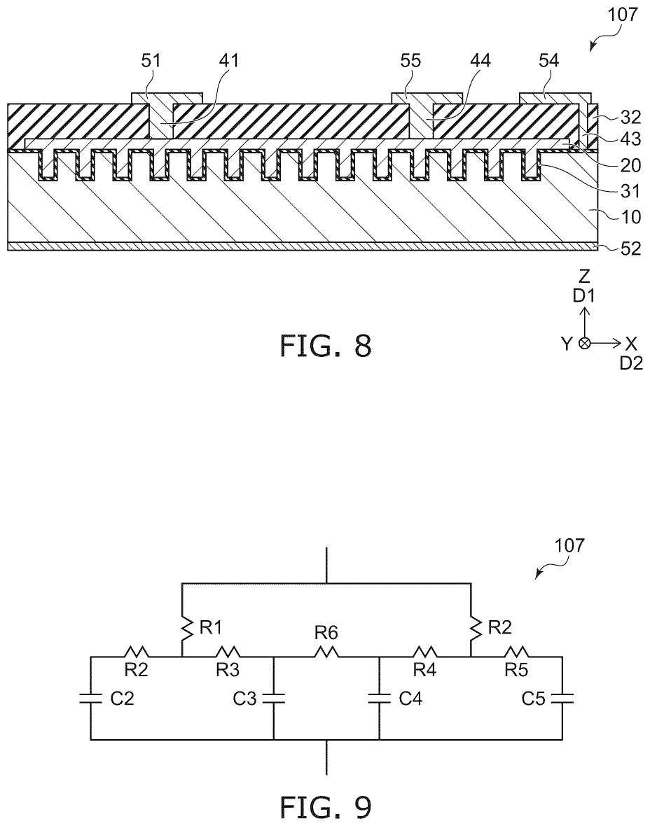

FIG. 8 is a schematic cross-sectional view illustrating a semiconductor device according to the embodiment.

FIG. 9 is an equivalent circuit diagram illustrating the semiconductor device according to the embodiment.

When R=ρs×L/W, C=Cs×L×W . . . (3) fT=1/(R×C) that is two times or more the operating frequency is unable to be satisfied with one via, a plurality of via resistance portions are used.

As shown in FIGS. 8 and 9, a semiconductor device 107 may further include a fourth via resistance portion 44. In the semiconductor device 107 shown in FIG. 8, the first conductive layer 51, a fifth conductive layer 55, and the second conductive layer 52 function as terminals. The configuration of the semiconductor device 107 may be otherwise similar to the configuration of the semiconductor device 101.

The fourth via resistance portion 44 is provided on a part of the first conductive member 20. The fourth via resistance portion 44 penetrates a part of the second insulating layer 32 in the first direction D1. The fourth via resistance portion 44 is electrically connected to the first conductive member 20.

The fourth via resistance portion 44 may include any of Al, Si, Cu, Ti, N, W, Co, or Ni. The fifth conductive layer 55 may include any of Al, Si, Cu, Ti, N, W, Co, or Ni.

The capacitors C2 to C5 shown in FIG. 9 correspond to the semiconductor member 10, the first conductive member 20, and the first insulating layer 31. The resistors R2 to R6 correspond to the first conductive member 20. The resistor R1 corresponds to the first via resistance portion 41. The resistor R2 corresponds to the fourth via resistance portion 44.

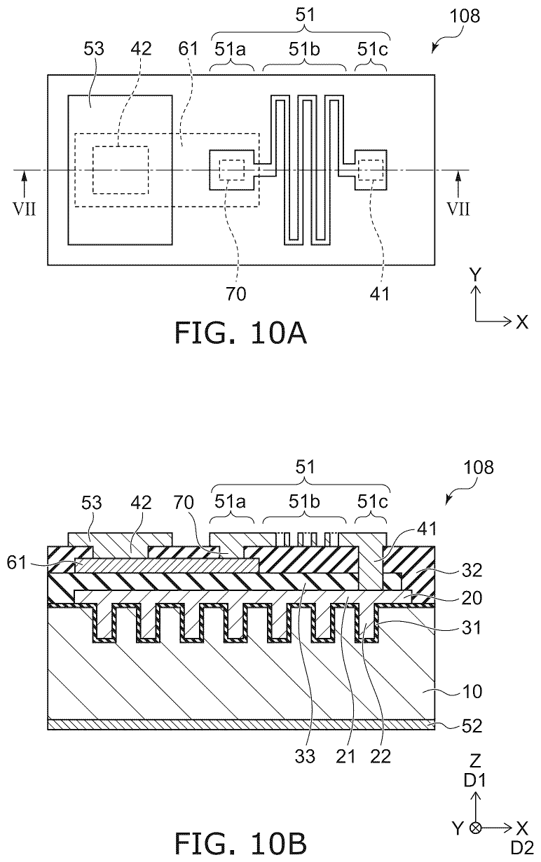

FIG. 10A is a schematic plan view illustrating a semiconductor device according to the embodiment.

FIG. 10B is a schematic cross-sectional view illustrating the semiconductor device according to the embodiment. FIG. 10B is a cross-sectional view taken along line VII-VII of FIG. 10A.

As shown in FIGS. 10A and 10B, in a semiconductor device 108, the first conductive layer 51 includes the first portion 51a, the second portion 51b, and the third portion 51c. The second portion 51b is between the first portion 51a and the third portion 51c. The third portion 51c is on the first via resistance portion 41. The first portion 51a, the second portion 51b, and the third portion 51c are electrically connected to the first via resistance portion 41. The configuration of the semiconductor device 108 may be otherwise similar to the configuration of the semiconductor device 103.

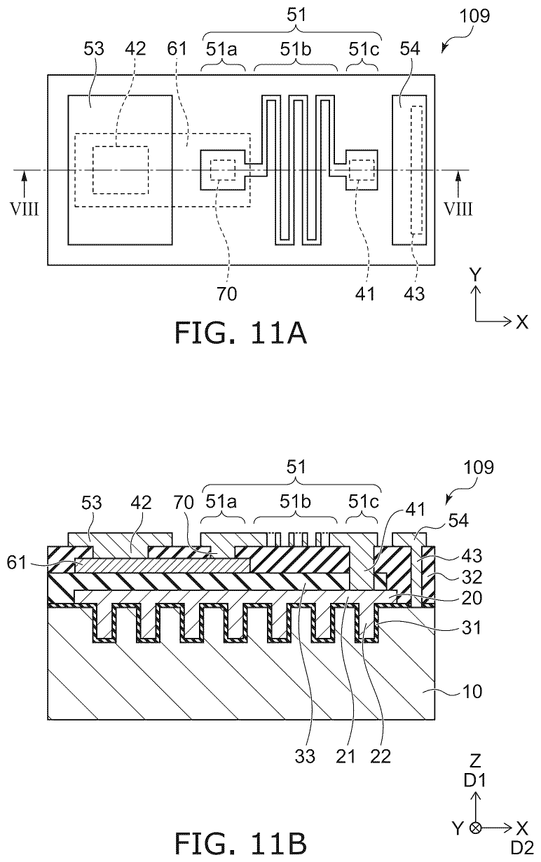

FIG. 11A is a schematic plan view illustrating a semiconductor device according to the embodiment.

FIG. 11B is a schematic cross-sectional view illustrating the semiconductor device according to the embodiment. FIG. 11B is a cross-sectional view taken along line VIII-VIII of FIG. 11A.

As shown in FIGS. 11A and 11B, in a semiconductor device 109, the first conductive layer 51 includes the first portion 51a, the second portion 51b, and the third portion 51c. The second portion 51b is between the first portion 51a and the third portion 51c. The third portion 51c is on the first via resistance portion 41. The first portion 51a, the second portion 51b, and the third portion 51c are electrically connected to the first via resistance portion 41. The configuration of the semiconductor device 109 may be otherwise similar to the configuration of the semiconductor device 106.

According to the embodiment, it is possible to provide a semiconductor device whose characteristics can be improved.

The embodiment includes the following forms.

### (Note 1)

A semiconductor device comprising:
a semiconductor member;
a first insulating layer provided on the semiconductor member;
a first conductive member provided on the first insulating layer;
a second insulating layer provided on the first conductive member;
a first via resistance portion provided on a part of the first conductive member, penetrating a part of the second insulating layer in a first direction, and electrically connected to the first conductive member;
a first conductive layer provided on the first via resistance portion and electrically connected to the first via resistance portion; and
a second conductive layer electrically connected to the semiconductor member,
the semiconductor member being provided on the second conductive layer,
the first conductive layer including a first portion, a second portion, and a third portion,
the second portion being between the first portion and the third portion,
the third portion being on the first via resistance portion, the first portion, the second portion, and the third portion being electrically connected to the first via resistance portion,
the second portion including a meander wiring.

### (Note 2)

A semiconductor device comprising:
a semiconductor member;
a first insulating layer provided on the semiconductor member;
a first conductive member provided on the first insulating layer;
a second insulating layer provided on the first conductive member;
a first via resistance portion provided on a part of the first conductive member, penetrating a part of the second insulating layer in a first direction, and electrically connected to the first conductive member;
a first conductive layer provided on the first via resistance
portion and electrically connected to the first via resistance portion;
a second conductive layer electrically connected to the semiconductor member;
a third insulating layer provided on a part of the first conductive member;
a first wiring resistance portion provided on the third insulating layer;
a second via resistance portion provided on a part of the first wiring resistance portion, penetrating a part of the second insulating layer in the first direction, and electrically connected to the first conductive layer via the first wiring resistance portion; and
a third conductive layer provided on the second via resistance portion,
the semiconductor member being provided on the second conductive layer.

### (Note 3)

A semiconductor device comprising:
a semiconductor member;
a first insulating layer provided on the semiconductor member;
a first conductive member provided on the first insulating layer;
a second insulating layer provided on the first conductive member;
a first via resistance portion provided on a part of the first
conductive member, penetrating a part of the second insulating layer in a first direction, and electrically connected to the first conductive member;
a third via resistance portion provided on the semiconductor member, penetrating the first insulating layer and a part of the second insulating layer in the first direction, and electrically connected to the semiconductor member; and
a fourth conductive layer provided on the third via resistance portion and electrically connected to the semiconductor member via the third via resistance portion,
the first conductive layer including a first portion, a second portion, and a third portion,
the second portion being between the first portion and the third portion,
the third portion being on the first via resistance portion,
the first portion, the second portion, and the third portion being electrically connected to the first via resistance portion,
the second portion including a meander wiring.

### (Note 4)

A semiconductor device comprising:
a semiconductor member;
a first insulating layer provided on the semiconductor member;
a first conductive member provided on the first insulating layer;
a second insulating layer provided on the first conductive member;
a first via resistance portion provided on a part of the first conductive member, penetrating a part of the second insulating layer in a first direction, and electrically connected to the first conductive member;
a third via resistance portion provided on the semiconductor member, penetrating a part of the first insulating layer and a part of the second insulating layer in the first direction, and electrically connected to the semiconductor member;
a fourth conductive layer provided on the third via resistance portion and electrically connected to the semiconductor member via the third via resistance portion;
a first conductive layer provided on the first via resistance portion and electrically connected to the first via resistance portion;
a third insulating layer provided on a part of the first conductive member;
a first wiring resistance portion provided on a part of the third insulating layer;
a second via resistance portion provided on the first wiring resistance portion, penetrating a part of the second insulating layer in the first direction, and electrically connected to the first conductive layer via the first wiring resistance portion; and
a third conductive layer provided on the second via resistance portion.

### (Note 5)

The semiconductor device according to Note 2 or 4, wherein
the first conductive layer includes a first portion, a second portion, and a third portion, and
the second portion includes a meander wiring.

### (Note 6)

The semiconductor device according to Note 2 or 4, wherein
a resistance of the first wiring resistance portion is larger than a resistance of the first via resistance portion, and
the resistance of the first wiring resistance portion is larger than a resistance of the second via resistance portion.

The semiconductor device according to Note 2 or 4, wherein
the first conductive layer and the third conductive layer include metal, and
the first wiring resistance portion includes polysilicon.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as the semiconductor layers, electrodes, insulating layer, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor member;
a first insulating layer provided on the semiconductor member;
a first conductive member provided on the first insulating layer;
a second insulating layer provided on the first conductive member;
a first via resistance portion provided on a part of the first conductive member, penetrating a part of the second insulating layer in a first direction, and electrically connected to the first conductive member;
a first conductive layer provided on the first via resistance portion and electrically connected to the first via resistance portion; and
a second conductive layer electrically connected to the semiconductor member,
the semiconductor member being provided on the second conductive layer.

2. The semiconductor device according to claim 1, wherein
the first conductive layer includes a first portion, a second portion, and a third portion,
the second portion is provided between the first portion and the third portion,
the third portion is provided on the first via resistance portion, and
the first portion, the second portion, and the third portion are electrically connected to the first via resistance portion.

3. The semiconductor device according to claim 2, wherein
the second portion includes a meander wiring.

4. The semiconductor device according to claim 1, further comprising:
a third insulating layer provided on a part of the first conductive member and interposed between the first conductive member and the second insulating layer;
a first wiring resistance portion provided on the third insulating layer and interposed between the third insulating layer and the second insulating layer;
a connection portion provided on a part of the first wiring resistance portion, electrically connecting the first wiring resistance portion and the first conductive layer, and penetrating a part of the second insulating layer in the first direction;
a second via resistance portion provided on a part of the first wiring resistance portion, electrically connected to the first wiring resistance portion, penetrating a part of the second insulating layer in the first direction, and electrically connected to the first conductive layer via the first wiring resistance portion; and
a third conductive layer provided on the second via resistance portion.

5. The semiconductor device according to claim 4, wherein
the first conductive layer includes a first portion, a second portion, and a third portion,
the second portion is provided between the first portion and the third portion,
the third portion is provided on the first via resistance portion, and
the first portion, the second portion, and the third portion are electrically connected to the first via resistance portion.

6. A semiconductor device comprising:
a semiconductor member;
a first insulating layer provided on the semiconductor member;
a first conductive member provided on the first insulating layer;
a second insulating layer provided on the first conductive member;
a first via resistance portion provided on a part of the first conductive member, penetrating a part of the second insulating layer in a first direction, and electrically connected to the first conductive member;
a third via resistance portion provided on the semiconductor member, penetrating a part of the first insulating layer and a part of the second insulating layer in the first direction, and electrically connected to the semiconductor member;
a fourth conductive layer provided on the third via resistance portion and electrically connected to the semiconductor member via the third via resistance portion; and
a first conductive layer provided on the first via resistance portion and electrically connected to the first via resistance portion.

7. The semiconductor device according to claim 6, wherein
the first conductive layer includes a first portion, a second portion, and a third portion,
the second portion is provided between the first portion and the third portion,
the third portion is provided on the first via resistance portion, and
the first portion, the second portion, and the third portion are electrically connected to the first via resistance portion.

8. The semiconductor device according to claim 7, wherein
the second portion includes a meander wiring.

9. The semiconductor device according to claim 6, further comprising:
a third insulating layer provided on a part of the first conductive member and interposed between the first conductive member and the second insulating layer;
a first wiring resistance portion provided on the third insulating layer and interposed between the third insulating layer and the second insulating layer;
a connection portion provided on a part of the first wiring resistance portion, electrically connecting the first wiring resistance portion and the first conductive layer, and penetrating a part of the second insulating layer in the first direction;
a second via resistance portion provided on a part of the first wiring resistance portion, electrically connected to the first wiring resistance portion, penetrating a part of the second insulating layer in the first direction, and electrically connected to the first conductive layer via the first wiring resistance portion; and
a third conductive layer provided on the second via resistance portion.

10. The semiconductor device according to claim 9, wherein
the first conductive layer includes a first portion, a second portion, and a third portion,
the second portion is provided between the first portion and the third portion,
the third portion is provided on the first via resistance portion, and
the first portion, the second portion, and the third portion are electrically connected to the first via resistance portion.

11. The semiconductor device according to claim 4, wherein
a resistance of the first wiring resistance portion is larger than a resistance of the first via resistance portion, and
the resistance of the first wiring resistance portion is larger than a resistance of the second via resistance portion.

12. The semiconductor device according to claim 4, wherein
the first conductive layer and the third conductive layer include metal, and
the first wiring resistance portion includes polysilicon.

13. The semiconductor device according to claim 1, wherein
the first conductive member includes a first conductive region and a plurality of protruding portions,
the plurality of protruding portions are provided between the semiconductor member and the first conductive region.

14. The semiconductor device according to claim 6, wherein
the first conductive member includes a first conductive region and a plurality of protruding portions,
the plurality of protruding portions are provided between the semiconductor member and the first conductive region.
